(19) United States
(12) Patent Application Publication
(10) Pub. No.: US 2026/0271470 A1
(43) Pub. Date: Sep. 10, 2026

(54) DISPLAY DEVICE AND ELECTRONIC DEVICE

(71) Applicant: Samsung Display Co., Ltd., Yongin-si (KR)

(72) Inventors: KIBUM KIM, Yongin-si (KR); SOOCHUL KIM, Yongin-si (KR); Tae Gyun KIM, Yongin-si (KR); Youngchul SIM, Yongin-si (KR); SOYOUNG LEE, Yongin-si (KR); WONHO LEE, Yongin-si (KR)

(21) Appl. No.: 19/343,890

(22) Filed: Sep. 29, 2025

(30) Foreign Application Priority Data
Mar. 5, 2025 (KR) 10-2025-0028459

(51) Int. Cl. H10H 29/856; H10H 29/49

(52) U.S. Cl. CPC H10H 29/856; H10H 29/49

(57) ABSTRACT

A display device according to one or more embodiments includes a substrate, a first common electrode above the substrate, a second common electrode above the first common electrode and defining first openings, first light-emitting elements respectively overlapping the first openings in plan view, connected to the first common electrode, below the first common electrode, and arranged in a first direction parallel to a top surface of the substrate, and second light-emitting elements connected to the second common electrode, below the second common electrode, and arranged in a second direction parallel to the top surface of the substrate.

### CROSS-REFERENCE TO RELATED APPLICATION

The present application claims priority to, and the benefit of, Korean Patent Application No. 10-2025-0028459, filed on Mar. 5, 2025, in the Korean Intellectual Property Office, the entire disclosure of which is incorporated herein by reference.

### BACKGROUND

### 1. Field

The present disclosure relates to a display device and an electronic device.

### 2. Description of the Related Art

A display device includes a plurality of pixels that are units for displaying images. Each pixel may include a pixel circuit unit and a light-emitting unit connected thereto. The light-emitting unit may be implemented in various forms, for instance, may include a light-emitting diode as a light-emitting element. Light-emitting diodes may have various sizes, and recently, micro-scale or nano-scale ultra-small light-emitting diodes using II-VI Group or III-V Group compound semiconductors are being developed.

The light-emitting diode may be directly formed on a substrate included in the display device or may be mounted on the substrate in a chip form. The light-emitting diode may emit light of one of several primary colors.

A pixel circuit unit for driving the light-emitting diode may be integrated on the substrate or may be included in the light-emitting diode chip. The pixel circuit unit may include a plurality of transistors and at least one capacitor. The pixel circuit unit controls an amount of driving current delivered to the light-emitting diode so that each pixel may emit light of desired luminance.

### SUMMARY

Embodiments relate to a display device and an electronic device for improving light extraction efficiency.

A display device according to one or more embodiments includes a substrate, a first common electrode above the substrate, a second common electrode above the first common electrode and defining first openings, first light-emitting elements respectively overlapping the first openings in plan view, connected to the first common electrode, below the first common electrode, and arranged in a first direction parallel to a top surface of the substrate, and second light-emitting elements connected to the second common electrode, below the second common electrode, and arranged in a second direction parallel to the top surface of the substrate.

The display device may further include a third common electrode above the second common electrode, and defining second openings overlapping one of the first light-emitting elements or the second light-emitting elements in plan view, and third light-emitting elements connected to the third common electrode, below the third common electrode, and arranged in a third direction parallel to the top surface of the substrate.

The display device may further include reflective barriers extending in a fourth direction perpendicular to the top surface of the substrate and including a first reflective barrier spaced apart from at least one of the first light-emitting elements, the second light-emitting elements, or the third light-emitting elements in plan view in a direction parallel to the top surface of the substrate, and a second reflective barrier overlapping at least one of the first light-emitting elements, the second light-emitting elements, or the third light-emitting elements in the fourth direction.

The display device may further include a reflective layer between the substrate and the first common electrode, and connected to the first reflective barrier.

The display device may further include a first filling layer between the substrate and the first common electrode, a second filling layer between the first common electrode and the second common electrode, and a third filling layer between the second common electrode and the third common electrode.

The display device may further include a planarization layer above the third common electrode.

The first openings may be filled with the third filling layer, wherein the second openings are filled with the planarization layer.

The display device may further include optical elements above the planarization layer and respectively overlapping the first light-emitting elements, the second light-emitting elements, and the third light-emitting elements.

The display device may further include a first lower electrode below, and connected to, one of the first light-emitting elements, a second lower electrode below, and connected to, one of the second light-emitting elements, and a third lower electrode below, and connected to, one of the third light-emitting elements.

The display device may further include pixel-driving circuits above the substrate, at least one of the pixel-driving circuits being electrically connected to the first lower electrode through a first wiring layer.

The second lower electrode may be electrically connected to at least one of the pixel-driving circuits through a second wiring layer and the second reflective barrier.

The reflective barriers may include a conductive material.

The first light-emitting elements, the second light-emitting elements, and the third light-emitting elements may include a first semiconductor layer, an active layer above the first semiconductor layer, and a second semiconductor layer above the active layer.

The first semiconductor layer and the second semiconductor layer may include at least one of II-VI Group nitrides, II-VI Group phosphides, III-V Group nitrides, or III-V Group phosphides.

The display device may further include a current-spreading layer above the second semiconductor layer.

A display device according to one or more embodiments includes a substrate, a first common electrode above the substrate, a second common electrode above the substrate, at a different layer from the first common electrode, and defining first openings, first light-emitting elements overlapping the first openings, electrically connected to the first common electrode, and configured to emit first color light, and second light-emitting elements electrically connected to the second common electrode and configured to emit second color light different from the first color light.

The display device may further include a third common electrode above the substrate, at a different layer from the first common electrode and the second common electrode, and defining second openings overlapping the first light-emitting elements or the second light-emitting elements, and third light-emitting elements electrically connected to the third common electrode and configured to emit third color light different from the first color light and the second color light.

The display device may further include reflective barriers extending in a direction perpendicular to a top surface of the substrate, and including a first reflective barrier spaced apart from at least one of the first light-emitting elements, the second light-emitting elements, or the third light-emitting elements in plan view in a direction parallel to the top surface of the substrate, and a second reflective barrier overlapping at least one of the first light-emitting elements, the second light-emitting elements, or the third light-emitting elements in plan view.

The display device may further include a reflective layer between the substrate and the first common electrode and connected to the first reflective barrier.

An electronic device according to one or more embodiments includes a processor, and a display module connected to the processor, and including a substrate, a first common electrode above the substrate, a second common electrode above the first common electrode and defining first openings, first light-emitting elements respectively overlapping the first openings in plan view, below the first common electrode, and connected to the first common electrode, and second light-emitting elements below the second common electrode and connected to the second common electrode.

According to the embodiments, it is possible to improve light extraction efficiency by reducing loss due to absorption and reflection of light emitted from light-emitting elements of the display device, and to reduce or prevent color mixing with light emitted from adjacent pixels.

### BRIEF DESCRIPTION OF THE DRAWINGS

FIG. 1 is a cross-sectional view of a display area of a display device according to one or more embodiments.

FIG. 2 is a plan view of a display area of a display device according to one or more embodiments.

FIG. 3 is a plan view of a second common electrode of a display device according to one or more embodiments.

FIG. 4 is a plan view of a third common electrode of a display device according to one or more embodiments.

FIG. 5 is a cross-sectional view of a pixel of a display device according to one or more embodiments.

FIG. 6 is a cross-sectional view of a display device according to one or more embodiments.

FIG. 7 is a block diagram of an electronic device according to one or more embodiments.

FIG. 8 shows schematic diagrams of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

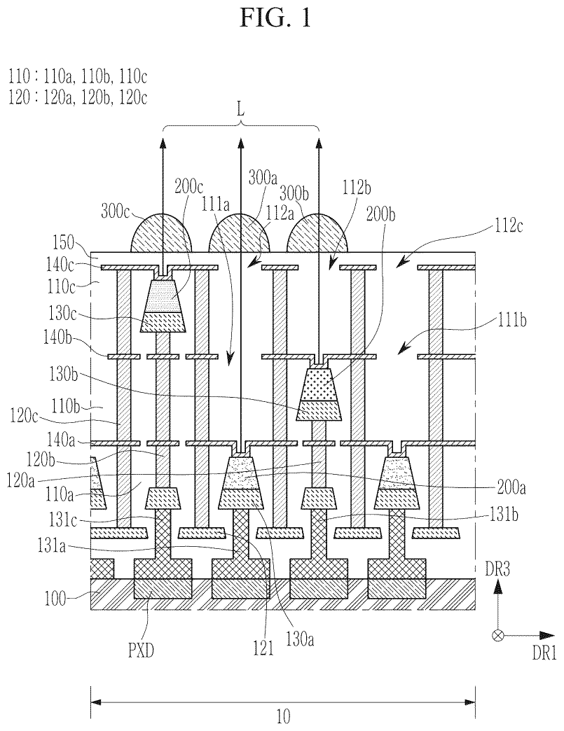

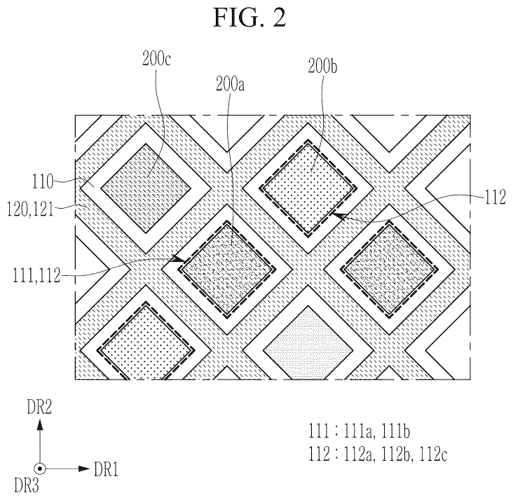

Hereinafter, a display area 10 of a display device according to one or more embodiments will be described with reference to FIGS. 1 and 2.

FIG. 1 is a cross-sectional view of a display area 10 of a display device according to one or more embodiments. FIG. 2 is a plan view of a display area 10 of a display device according to one or more embodiments.

Referring to FIG. 1, a display device according to one or more embodiments may include a display area 10 capable of displaying images. The display area 10 may include a substrate 100, a plurality of first, second, and/or third light-emitting elements 200a, 200b, and/or 200c positioned on the substrate 100, first, second, and/or third filling layers 110a, 110b, 110c, a reflective layer 121, a reflective barrier 120, first, second, and/or third common electrodes 140a, 140b, and/or 140c, a planarization layer 150, and first, second, and/or third optical elements 300a, 300b, and/or 300c (as used herein, “positioned on” or “located on” may mean “above”).

A pixel-driving circuit PXD may be located on the substrate 100. The pixel-driving circuit PXD may include driver circuits other than CMOS driver circuits. For instance, the pixel-driving circuit PXD may include a thin film transistor (TFT) driver circuit or may be a circuit using III-V Group semiconductors. In one or more embodiments, the substrate 100 may be a Si substrate and may be a transparent substrate, for instance, a glass substrate. In addition, the substrate may include GaAs, GaP, InP, SiC, ZnO, and/or sapphire substrates.

A plurality of pixels corresponding to a plurality of pixel-driving circuits PXD may be positioned on the substrate 100.

The pixel-driving circuit PXD is configured to drive light-emitting elements positioned in each pixel. The pixel-driving circuit PXD may be connected to the light-emitting elements of each pixel to each other. The pixel-driving circuit PXD may have a one-to-one correspondence between the pixel-driving circuit PXD and the light-emitting elements of each pixel, but a one-to-one correspondence between the pixel-driving circuit PXD and the light-emitting elements of each pixel may not be desirable. For instance, there may be two or more light-emitting elements connected to the same pixel-driving circuit PXD output to create redundancy, and even if an error occurs in one of the light-emitting elements, the remaining light-emitting elements may still emit light from the pixel.

Each pixel may include a light-emitting element 200a, 200b, or 200c.

The first light-emitting element 200a may be stacked on, or above, the substrate 100 and the pixel-driving circuit PXD. The plurality of first light-emitting elements 200a may be arranged in a direction parallel to the top surface of the substrate 100 in a layer on the substrate 100. For instance, referring to FIG. 2, the plurality of first light-emitting elements 200a may be arranged in a first direction DR1. The plurality of first light-emitting elements 200a may emit light of any one color among red, green, or blue.

The second light-emitting element 200b may be positioned above (e.g., at a level that is above) the first light-emitting element 200a in cross-sectional view. The plurality of second light-emitting elements 200b may be arranged in a direction parallel to the top surface of the substrate 100 in a layer on the substrate 100. For instance, referring to FIG. 2, the plurality of second light-emitting elements 200b may be arranged in a diagonal direction that is different from the first direction DR1 and the second direction DR2. The plurality of second light-emitting elements 200b may emit light of any one color among red, green, or blue, and may emit light of a different color from the light emitted by the first light-emitting element 200a.

The third light-emitting element 200c may be positioned above (e.g., at a level above) the second light-emitting element 200b in cross-sectional view. The plurality of third light-emitting elements 200c may be arranged in a direction parallel to the top surface of the substrate 100 in a layer on the substrate 100. For instance, referring to FIG. 2, the plurality of third light-emitting elements 200c may be arranged in a diagonal direction different from the first direction DR1 and the second direction DR2. The direction in which the plurality of second light-emitting elements 200b are arranged and the direction in which the plurality of third light-emitting elements 200c are arranged may be different from each other. The third light-emitting elements may emit light of any one color among red, green, or blue, and may emit a different color from the light emitted by the plurality of first light-emitting elements 200a and the plurality of second light-emitting elements 200b.

The first light-emitting element 200a may be electrically connected to the pixel-driving circuit PXD through a first lower electrode 130a and through a first wiring layer 131a positioned below the first light-emitting element 200a. A driving voltage may be independently applied to each of the plurality of first light-emitting elements 200a through the first lower electrode 130a.

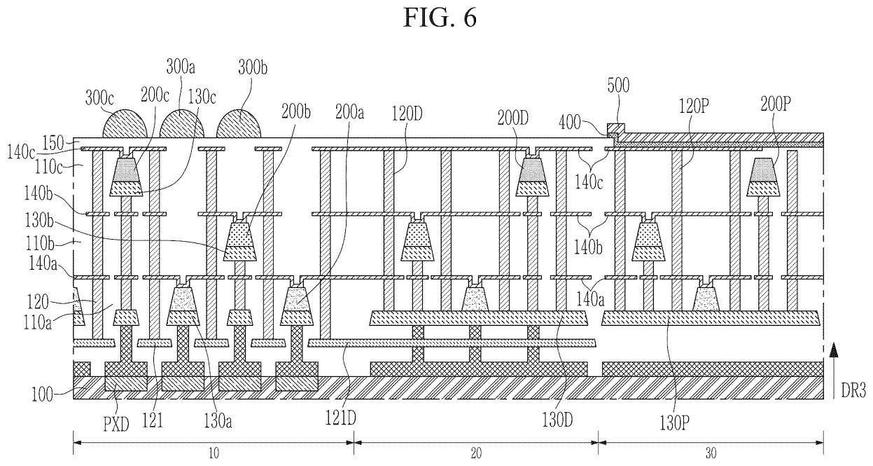

The first common electrode 140a may be positioned above the plurality of first light-emitting elements 200a in cross-sectional view. The first common electrode 140a may be electrically connected to the plurality of first light-emitting elements 200a positioned below the first common electrode 140a and arranged in a direction parallel to the top surface of the substrate 100 to transmit a common voltage. The first common electrode 140a may receive a common voltage through a pad portion of a pad area (shown as 30 in FIG. 6) to be described later and through a conductive layer connected thereto (for instance, the reflective barrier 120P or the conductive layer 400 of FIG. 6). The first common electrode 140a may be a transparent electrode, such as indium tin oxide (ITO). Because the first common electrode 140a is positioned above the first light-emitting element 200a, it may be configured to transmit light emitted from the first light-emitting element 200a.

The second light-emitting element 200b may be electrically connected to the pixel-driving circuit PXD through a second lower electrode 130b and a second wiring layer 131b positioned below the second light-emitting element 200b. A driving voltage may be independently applied to each of the second light-emitting elements 200b through the second lower electrode 130b.

The second common electrode 140b may be positioned above the first common electrode 140a and the plurality of second light-emitting elements 200b in cross-sectional view. The second common electrode 140b may be electrically connected to the plurality of second light-emitting elements 200b positioned below the second common electrode 140b and may be arranged in a direction parallel to the top surface of the substrate 100 to transmit a common voltage. The second common electrode 140b may receive a common voltage through a pad portion of a pad area (shown as 30 in FIG. 6) to be described later and through a conductive layer connected thereto (for instance, the reflective barrier 120P or the conductive layer 400 of FIG. 6). The second common electrode 140b may also be a transparent electrode, such as indium tin oxide (ITO). Because the second common electrode 140b is positioned above the plurality of first light-emitting elements 200a and the plurality of second light-emitting elements 200b, it may be configured to transmit light emitted from the first light-emitting elements 200a and from the second light-emitting elements 200b.

The third light-emitting element 200c may be electrically connected to the pixel-driving circuit PXD through a third lower electrode 130c and a third wiring layer 131c positioned below the third light-emitting element 200c. A driving voltage may be independently applied to each of the third light-emitting elements 200c through the third lower electrode 130c.

The third common electrode 140c may be positioned above the second common electrode 140b and the plurality of third light-emitting elements 200c in cross-sectional view. The third common electrode 140c may be electrically connected to the plurality of third light-emitting elements 200c positioned below the third common electrode 140c and arranged in a direction parallel to the top surface of the substrate 100 to transmit a common voltage. The third common electrode 140c may receive a common voltage through a pad portion of a pad area (shown as 30 in FIG. 6) to be described later and a conductive layer connected thereto (for instance, the reflective barrier 120P or the conductive layer 400 of FIG. 6). The third common electrode 140c may also be a transparent electrode, such as indium tin oxide (ITO). Because the third common electrode 140c is positioned above the plurality of first, second, and/or third light-emitting elements 200a, 200b, and/or 200c, it may be configured to transmit light emitted from the first, second, and third light-emitting elements 200a, 200b, and/or 200c.

Here, the first, second, and/or third lower electrodes 130a, 130b, and/or 130c may be anodes, which are hole injection electrodes, and the first, second, and/or third common electrodes 140a, 140b, and/or 140c may be cathodes, which are electron injection electrodes. However, the disclosure is not necessarily limited thereto, and depending on the driving method of the display device, the first, second, and/or third lower electrodes 130a, 130b, and/or 130c may be cathodes, and the first, second, and/or third common electrodes 140a, 140b, and/or 140c may be anodes.

A filling layer 110 may be positioned between the substrate 100 and the first common electrode 140a, between the first common electrode 140a and the second common electrode 140b, and between the second common electrode 140b and the third common electrode 140c. The filling layer 110 may include a first filling layer 110a positioned between the substrate 100 and the first common electrode 140a, a second filling layer 110b positioned between the first common electrode 140a and the second common electrode 140b, and a third filling layer 110c positioned between the second common electrode 140b and the third common electrode 140c.

The filling layer 110 may flatten, or planarize, the top surface of a layer adjacent thereto and facilitate formation of a layer stacked on the filling layer 110. As a material of the filling layer 110, silicon oxide or silicon nitride having non-conductivity and transparency may be used, thus allowing light generated by the light-emitting elements to pass through the filling layer. Even in case that the filling layer 110 is positioned to overlap the first, second, and/or third light-emitting elements 200a, 200b, and/or 200c in plan view, because it is transparent in a region overlapping the first, second, and/or third light-emitting elements 200a, 200b, and/or 200c in the third direction DR3, light generated by the first, second, and/or third light-emitting elements 200a, 200b, and/or 200c positioned below the filling layer 110 may be propagated to the outside through the transparent filling layer 110.

The first, second, and/or third common electrodes 140a, 140b, and/or 140c may be transparent electrodes, such as indium tin oxide (ITO). This is because light emitted from the first, second, and/or third light-emitting elements 200a, 200b, and/or 200c positioned below the first, second, and/or third common electrodes 140a, 140b, and/or 140c may be allowed to pass through. However, although the common electrode 140 is transparent, the stacked structure of the first common electrode 140a, the second common electrode 140b, and the third common electrode 140c may partially absorb light emitted from the light-emitting element 200, which may reduce light transmittance and/or cause light output loss. In addition, because the materials of the first, second, and/or third filling layers 110a, 110b, 110c respectively positioned between the first, second, and/or third common electrodes 140a, 140b, and/or 140c and the materials of the first, second, and/or third common electrodes 140a, 140b, and/or 140c are different, optical loss may occur due to light reflection due to a difference in refractive index. Furthermore, the first, second, and/or third common electrodes 140a, 140b, and/or 140c may act as waveguides, and light emitted from each light-emitting element 200a, 200b, and/or 200c along the first, second, and/or third common electrodes 140a, 140b, and/or 140c may be guided and may leak to adjacent pixels. The first light-emitting element 200a, the second light-emitting element 200b, and the third light-emitting element 200c emit light of different respective colors, and in case that light emitted from each light-emitting element 200a, 200b, and/or 200c leaks to adjacent pixels, color quality of the display device may be degraded due to color mixing.

Therefore, to reduce or prevent light loss and color mixing, the second common electrode 140b may have a plurality of first openings 111a and/or 111b, and the third common electrode 140c may have a plurality of second openings 112a, 112b, and/or 112c.

The second common electrode 140b may include a plurality of first openings 111a and/or 111b. The plurality of first openings 111a and/or 111b may overlap the plurality of first light-emitting elements 200a. Light emitted from the plurality of first light-emitting elements 200a may be output through the plurality of first openings 111a and/or 111b. The plurality of first openings 111a and/or 111b may overlap the first light-emitting elements 200a in plan view so that light emitted from the first light-emitting elements 200a may not be absorbed and reflected by the second common electrode 140b. The amount of light that is guided by the second common electrode 140b and is unable to be emitted to the outside may also be reduced.

The third common electrode 140c may include a plurality of second openings 112a, 112b, and/or 112c. The plurality of second openings 112a, 112b, and/or 112c may overlap the plurality of first light-emitting elements 200a or the plurality of second light-emitting elements 200b. Light emitted from the plurality of first light-emitting elements 200a and the plurality of second light-emitting elements 200b may be output through the plurality of second openings 112a, 112b, and/or 112c. The plurality of second openings 112a, 112b, and/or 112c may overlap the first light-emitting elements 200a and the second light-emitting elements 200b in plan view so that light emitted from the first light-emitting elements 200a and the second light-emitting elements 200b may not be absorbed and reflected by the third common electrode 140c. The amount of light that is guided by the third common electrode 140c and that is unable to be emitted to the outside may also be reduced.

The display device according to one or more embodiments patterns the second common electrode 140b and the third common electrode 140c to form a plurality of openings 111 and/or 112, which reduces absorption and reflection of light emitted in the third direction DR3 from the light-emitting elements 200a and/or 200b positioned below the second common electrode 140b and the third common electrode 140c, and reduces or prevents the likelihood of the common electrodes 140b and/or 140c guiding light and causing light to leak to adjacent pixels, which improves color quality and light extraction efficiency.

Referring to FIG. 1 again, the display device according to one or more embodiments may include a plurality of reflective barriers 120 respectively connected to at least one of the first common electrode 140a, the second common electrode 140b, or the third common electrode 140c. The reflective barriers 120 may extend approximately in the third direction DR3.

The plurality of reflective barriers 120 may include a reflective barrier 120c adjacent to at least one of the first light-emitting element 200a, the second light-emitting element 200b, or the third light-emitting element 200c in a direction parallel to the top surface of the substrate 100. In addition, the plurality of reflective barriers 120 may further include reflective barriers 120a and/or 120b, which overlap the second light-emitting element 200b or the third light-emitting element 200c in the third direction DR3.

Light L emitted from the first, second, and/or third light-emitting elements 200a, 200b, and/or 200c may be reflected by the reflective barriers 120 to reduce or prevent light from leaking to adjacent pixels, which helps light to be well emitted to the outside from the corresponding pixel. For instance, light emitted from the first light-emitting element 200a may be reflected by the reflective barriers 120 positioned on both sides of the first light-emitting element 200a so that light does not leak sideways and may be emitted toward the optical element 300a overlapping the first light-emitting element 200a. In addition, light emitted from the second light-emitting element 200b may also be reflected by the reflective barriers 120 positioned on both sides so that light does not leak sideways and may be emitted toward the optical element 300b overlapping the second light-emitting element 200b.

The reflective barrier 120 may serve to spread current or voltage. The reflective barrier 120 may include a conductive material. For instance, the reflective barrier 120 may include metals, such as Cu, and may improve reflectance through high-reflectance metal coatings, such as Ag, Al, Au, Pt. In case that power is applied to the first, second, and/or third common electrodes 140a, 140b, and/or 140c, if there is no reflective barrier 120, current-spreading may not occur properly to the display area, and voltage drop (IR drop) may occur.

The reflective barrier 120 may include a first reflective barrier 120a, a second reflective barrier 120b, and a third reflective barrier 120c.

The first reflective barrier 120a may overlap the second light-emitting element 200b in the third direction DR3. The second lower electrode 130b may be electrically connected to the pixel-driving circuit PXD through the second wiring layer 131b and through the first reflective barrier 120a connected to the second wiring layer 131b. The first reflective barrier 120a may electrically connect between the second wiring layer 131b and the second lower electrode 130b.

The second reflective barrier 120b may overlap the third light-emitting element 200c in the third direction DR3. The third lower electrode 130c may be electrically connected to the pixel-driving circuit PXD through the third wiring layer 131c and through the second reflective barrier 120b connected to the third wiring layer 131c. The second reflective barrier 120b may electrically connect between the third wiring layer 131c and the third lower electrode 130c.

The third reflective barrier 120c may not overlap the second light-emitting element 200b or the third light-emitting element 200c in the third direction DR3. The third reflective barrier 120c is positioned on the reflective layer 121 and may overlap the reflective layer 121 in the third direction DR3. The reflective layer 121 is positioned between the substrate 100 and the first common electrode 140a in cross-sectional view, and may be electrically connected to the third reflective barrier 120c. The reflective layer 121 allows light generated from the first, second, and/or third light-emitting elements 200a, 200b, and/or 200c to be emitted to the outside without heading toward the substrate 100. The reflective layer 121 may use high-reflectance metals, such as Ag, Al, Au, Pt.

The reflective layer 121 and the plurality of third reflective barriers 120c connected to the reflective layer 121 may be electrically connected to at least one of the first common electrode 140a, the second common electrode 140b, or the third common electrode 140c to transmit a common voltage. FIG. 1 shows one or more embodiments in which the plurality of third reflective barriers 120c are electrically connected to all of the first common electrode 140a, the second common electrode 140b, and the third common electrode 140c to transmit a common voltage.

A planarization layer 150 may be positioned on the third common electrode 140c. The planarization layer 150 planarizes the top surface of the display device and may be formed by, for instance, a CMP process.

A plurality of optical elements 300a, 300b, and/or 300c for improving light efficiency may be positioned on the planarization layer 150. The surface of each optical element 300a, 300b, and/or 300c may include a curved surface so that the optical elements 300a, 300b, and/or 300c may improve light efficiency through a light extraction effect. For instance, the optical elements 300a, 300b, and/or 300c may have a convex structure, a hemispherical structure, or a dome shape. The optical elements 300a, 300b, and/or 300c control the path of light by utilizing the curvature and refractive index difference of the surfaces of the optical elements 300a, 300b, and/or 300c, so that light generated from the first, second, and/or third light-emitting elements 200a, 200b, and/or 200c may be effectively emitted to the outside by the optical elements 300a, 300b, and/or 300c, which improves light efficiency.

The light-emitting elements 200a, 200b, and/or 200c according to one or more embodiments may constitute a light-emitting diode of each pixel together with the common electrodes 140a, 140b, and/or 140c and the lower electrodes 130a, 130b, and/or 130c connected thereto. Depending on the embodiments described, the light-emitting elements 200a, 200b, and/or 200c may be called light-emitting units, and the light-emitting diode may be called a light-emitting element.

Referring to FIG. 2, different light-emitting elements 200a, 200b, and/or 200c, which emit different respective colors may be partitioned by the reflective barriers 120 and the reflective layer 121 in plan view. Therefore, in case that the display device is viewed from the third direction DR3, the first light-emitting element 200a, the second light-emitting element 200b, and the third light-emitting element 200c may be positioned spaced apart from each other.

In case that the display device according to one or more embodiments is viewed from the third direction DR3, the filling layer 110 is filled in an area partitioned by the reflective barriers 120 and the reflective layer 121 in an area that is wider than the area where the first, second, and/or third light-emitting elements 200a, 200b, and/or 200c are positioned. The filling layer 110 is positioned adjacent to the first, second, and/or third light-emitting elements 200a, 200b, and/or 200c in the first direction DR1, the second direction DR2, and the third direction DR3, and overlaps the first, second, and/or third light-emitting elements 200a, 200b, and/or 200c in the third direction DR3. Because silicon oxide or silicon nitride having non-conductivity and transparency is used as the material of the filling layer 110, the first, second, and/or third light-emitting elements 200a, 200b, and/or 200c may be visible from the outside in plan view, and light may be emitted to the outside from the first, second, and/or third light-emitting elements 200a, 200b, and/or 200c through the transparent filling layer 110.

The first light-emitting element 200a may overlap the first opening 111 of the second common electrode 140b and the second opening 112 of the third common electrode 140c in plan view. Because the second common electrode 140b and the third common electrode 140c are removed from the first and second openings 111 and 112 above the first light-emitting element 200a, light emitted from the first light-emitting element 200a may not be absorbed and reflected by the second common electrode 140b and the third common electrode 140c, and the amount of light guided by the second common electrode 140b and the third common electrode 140c may also be reduced, which improves light efficiency.

The second light-emitting element 200b may overlap the second opening 112 of the third common electrode 140c in plan view. Because the third common electrode 140c is removed from the second opening 112 above the second light-emitting element 200b, light emitted from the second light-emitting element 200b may not be absorbed and reflected by the third common electrode 140c, and the amount of light guided by the third common electrode 140c may also be reduced, which improves light efficiency.

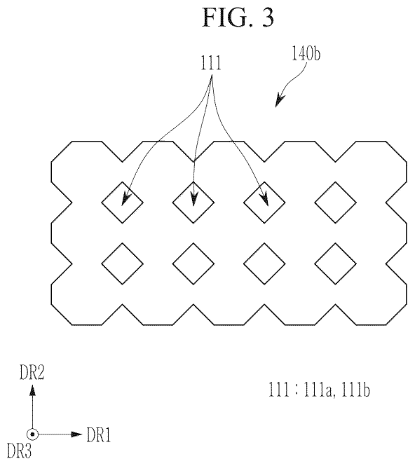

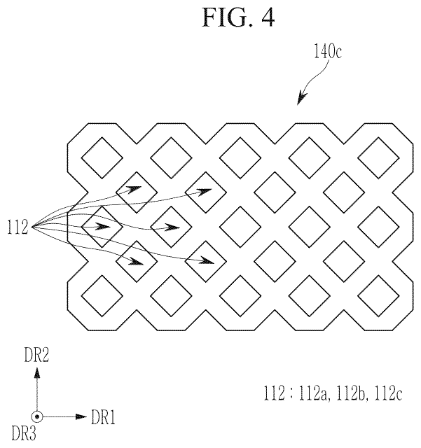

Hereinafter, plan views of the second common electrode 140b and the third common electrode 140c of the display device will be described with reference to FIGS. 3 and 4 together with the drawings described above.

Referring to FIG. 3, the second common electrode 140b may include a plurality of first openings 111. The plurality of first openings 111 may include the first openings 111a and/or 111b shown in FIG. 1. Referring to FIG. 3 together with FIGS. 1 and 2, the first openings 111 may overlap the plurality of first light-emitting elements 200a in plan view, and may facilitate emission of light generated from the first light-emitting elements 200a.

Referring to FIG. 4, the third common electrode 140c may include a plurality of second openings 112. The plurality of second openings 112 may include the second openings 112a, 112b, and/or 112c shown in FIG. 1. Referring to FIG. 4 together with FIGS. 1 and 2, the second openings 112 may overlap the plurality of first light-emitting elements 200a and the plurality of second light-emitting elements 200b in plan view, and may facilitate emission of light generated from the first light-emitting elements 200a and the second light-emitting elements 200b.

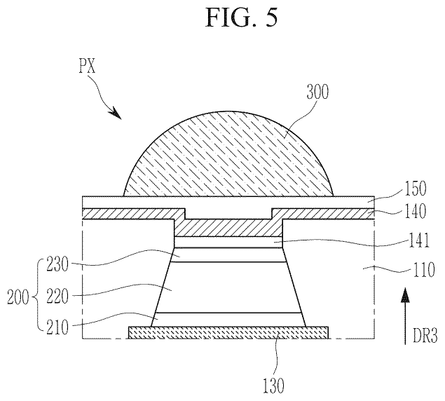

Hereinafter, the structure of a display device according to one or more embodiments will be described with reference to FIG. 5. FIG. 5 is a cross-sectional view showing a pixel of a display device according to one or more embodiments.

According to FIG. 5, a display device according to one or more embodiments includes a plurality of pixels PX, and each pixel PX may include a light-emitting element 200. A lower electrode 130 is positioned below the light-emitting element 200, and a common electrode 140 may be positioned above the light-emitting element 200. Alternatively, the light-emitting element 200 may be referred to as a light-emitting member and may be described as constituting a light-emitting element, which may be a light-emitting diode together with the lower electrode 130 and the common electrode 140.

A planarization layer 150 may be positioned on the common electrode 140, and light from the light-emitting element 200 may be emitted through the optical element 300 positioned on the planarization layer 150. A transparent filling layer 110 may be positioned surrounding the light-emitting element 200.

The light-emitting element 200 may have an epitaxial structure grown on a substrate. For instance, the light-emitting element 200 may be formed by being grown on a semiconductor substrate, such as a silicon wafer. For example, the light-emitting element 200 may include a first semiconductor layer 210, an active layer 220 on the first semiconductor layer 210, and a second semiconductor layer 230 on the active layer 220. The first semiconductor layer 210, the active layer 220, the second semiconductor layer 230, and the current-spreading layer 141 may have a vertical stacking structure in the third direction.

The first semiconductor layer 210 and the second semiconductor layer 230 may include II-VI Group or III-V Group compound semiconductor materials, for example, nitride semiconductor materials. For instance, the first semiconductor layer 210 and the second semiconductor layer 230 may include at least one nitride semiconductor material among InAlGaN, GaN, AlGaN, InGaN, AlN, and/or InN. The first semiconductor layer 210 and the second semiconductor layer 230 may serve to provide electrons and holes to the active layer 220. To this end, the first semiconductor layer 210 may be doped with a first conductivity type, and the second semiconductor layer 230 may be doped with a second conductivity type electrically opposite to the first conductivity type. For instance, the first semiconductor layer 210 may be doped with n-type, and the second semiconductor layer 230 may be doped with p-type, or conversely, the first semiconductor layer 210 may be doped with p-type, and the second semiconductor layer 230 may be doped with n-type. The n-type doped first semiconductor layer 210 or second semiconductor layer 230 may provide electrons to the active layer 220, and the p-type doped second semiconductor layer 230 or first semiconductor layer 210 may provide holes to the active layer 220.

The active layer 220 may be positioned between the first semiconductor layer 210 and the second semiconductor layer 230. The active layer 220 may have at least one quantum well structure in which quantum wells are located between barriers. Light may be generated as electrons and holes provided from the first semiconductor layer 210 and the second semiconductor layer 230 recombine in the quantum wells in the active layer 220. The wavelength of light generated in the active layer 220 may be determined according to the energy bandgap of the material constituting the quantum wells in the active layer 220. The active layer 220 may have only one quantum well, but may have a multi-quantum well (MQW) structure in which a plurality of quantum wells and a plurality of barriers are alternately arranged. The active layer 220 may include II-VI Group or III-V Group compound semiconductor materials, for example, nitride semiconductor materials. For instance, the active layer 220 may include at least one nitride semiconductor material among InGaN, GaN, AlGaN, and AlInGaN.

The color represented by each light-emitting element 200 may vary depending on the type and ratio of materials included in the active layer 220, or the material composition of the first semiconductor layer 210 and the second semiconductor layer 230.

The display device according to one or more embodiments may further include a current-spreading layer 141. The current-spreading layer 141 may be positioned on the second semiconductor layer 230, and may be electrically connected to the lower electrode 130 to function to spread current from the lower electrode 130 over a wider area. The current-spreading layer 141 may include conductive materials, such as ITO, TCO, and IZO. The current-spreading layer 141 may be omitted.

The lower electrode 130 may be electrically connected to the first semiconductor layer 210, and the common electrode 140 may be electrically connected to the second semiconductor layer 230. A driving voltage may be applied between the lower electrode 130 and the common electrode 140 to generate light in the active layer 220 of the light-emitting element 200. The lower electrode 130 and the common electrode 140 are insulated from each other. The lower electrode 130 may be an anode, and the common electrode 140 may be a cathode, or vice versa.

An optical element 300 for improving light efficiency may be further positioned on the planarization layer 150. The surface of the optical element 300 may include a curved surface so that the optical element 300 may improve light efficiency through a light extraction effect. For instance, the optical element 300 may have a convex structure, a hemispherical structure, or a dome shape. The optical element 300 may control the path of light so that light generated from the light-emitting element 200 may be effectively emitted to the outside by the optical element, which improves light efficiency.

FIG. 6 is a cross-sectional view of a display device according to one or more embodiments. The display device according to the one or more embodiments corresponding to FIG. 6 is mostly the same as the embodiments shown in FIGS. 1 to 5 described above, but may further include a dummy area 20 and a pad area 30 as well as the display area 10 of the display device.

The dummy area 20 and the pad area 30 may be areas which do not emit light in the display device. The dummy area 20 may be positioned on a side of the display area 10, and the pad area 30 may be positioned on a side of the dummy area 20.

The dummy area 20 of the display device may include dummy light-emitting elements 200D, but the dummy light-emitting elements 200D may not emit light. A CMP process may be used for planarization of each layer in the manufacturing process of the display device, and the pattern density of the lower layers may be configured to be constant to maintain process uniformity and to reduce or prevent defects due to excessive or insufficient removal. The dummy area 20 may be positioned for such constant pattern density. The dummy area 20 of the display device may have a stacking structure similar to the display area 10.

The pad area 30 of the display device may also include pad light-emitting elements 200P, but the pad light-emitting elements 200P may not emit light. The pad area 30 may have a stacking structure similar to the display area 10 and the dummy area 20.

In the pad area 30, the conductive layer 400 and the pad portion 500 may be positioned on the third filling layer 110c.

The pad portion 500 may include pads for connecting to a control unit or a driving unit of the display device. The pads of the pad portion 500 may transmit signals and voltages desirable for driving the light-emitting elements of the display area 10. The pad portion 500 may be exposed without being covered by an insulating layer, and may be electrically connected to a control unit or a driving unit, such as a printed circuit board or an IC chip.

The conductive layer 400 is positioned between the pad portion 500 and the third common electrode 140c, and may be electrically connected to the pad portion 500 and the third common electrode 140c. The third common electrode 140c may receive a common voltage transmitted from the pad portion 500 through the conductive layer 400. The third common electrode 140c may be formed as one electrode spanning the display area 10, the dummy area 20, and the pad area 30. Similarly, each of the first and second common electrodes 140a and/or 140b may also be formed as one electrode spanning the display area 10, the dummy area 20, and the pad area 30.

The dummy area 20 may include at least one reflective barrier 120D, and the pad area 30 may include at least one reflective barrier 120P. The reflective barriers 120D and/or 120P may have substantially the same characteristics as the reflective barrier 120 of the display area 10 described above. The reflective barriers 120D and/or 120P may be electrically connected to the first, second, and/or third common electrodes 140a, 140b, and/or 140c to transmit common voltages to the first, second, and/or third common electrodes 140a, 140b, and/or 140c.

The lower electrode 130D of the dummy light-emitting element 200D positioned in the lowest layer among the dummy light-emitting elements 200D positioned in the dummy area 20 may extend in a direction parallel to the top surface of the substrate 100, and may be connected to the plurality of reflective barriers 120D positioned in the dummy area 20 to transmit a common voltage. The lower electrode 130P of the pad light-emitting element 200P positioned in the lowest layer among the pad light-emitting elements 200P positioned in the pad area 30 may extend in a direction parallel to the top surface of the substrate 100, and may be connected to the plurality of reflective barriers 120P positioned in the pad area 30 to transmit a common voltage.

The dummy area 20 or the pad area 30 may further include a dummy reflective layer 121D positioned on the same layer as the reflective layer 121 of the display area 10. The dummy reflective layer 121D may extend in a direction parallel to the top surface of the substrate 100, and may be connected to at least one reflective barrier 120D to transmit a common voltage.

The display device may be applied to various electronic devices. An electronic device according to one or more embodiments includes the above-described display device, and may further include modules or devices having other additional functions in addition to the display device.

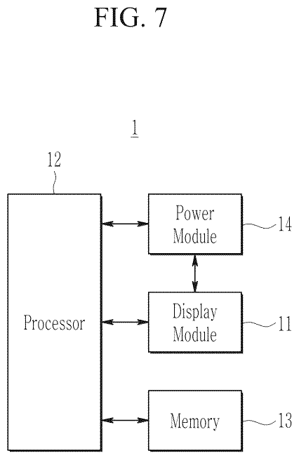

Hereinafter, electronic devices to which the display device may be applied will be described. FIG. 7 is a block diagram of an electronic device according to one or more embodiments.

Referring to FIG. 7, an electronic device 1 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information desirable for the operation of the processor 12 or the display module 11 may be stored in the memory 13. In case that the processor 12 executes an application stored in the memory 13, image data signals and/or input control signals are transmitted to the display module 11, and the display module 11 may process the provided signals to output image information through the display screen.

The power module 14 may include a power supply module, such as a power adapter or a battery device and a power conversion module, which converts power supplied by the power supply module to generate power desirable for the operation of the electronic device 1.

At least one of the components of the electronic device 1 described above may be included in the display device according to the embodiments described above. In addition, some of the individual modules functionally included in one module may be included in the display device and others may be provided separately from the display device. For instance, the display device may include the display module 11, and the processor 12, the memory 13, and the power module 14 may be provided in the form of other devices in the electronic device 1 other than the display device.

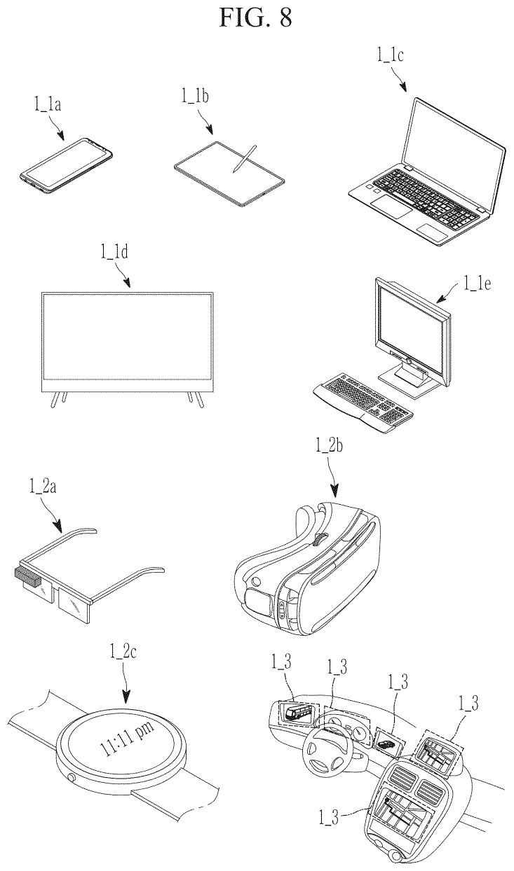

FIG. 8 shows schematic diagrams of electronic devices according to various embodiments.

Referring to FIG. 8, various electronic devices 1 to which the display device according to the embodiments is applied may include image display electronic devices, such as smartphones 1_1a, tablet PCs 1_1b, laptops 1_1c, TVs 1_1d, and desktop monitors 1_1e, as well as wearable electronic devices including display modules, such as smart glasses 1_2a, head mounted displays 1_2b, and smart watches 1_2c, and automotive electronic devices 1_3 including display modules, such as CID (Center Information Display) located on automobile instrument panels, center fascias, and dashboards, room mirror displays, and the like.

While the embodiments of the present disclosure have been described in detail above, the scope of the present disclosure is not limited thereto, and various modifications and improvements by those skilled in the art using the basic concept of the present disclosure defined in the following claims also belong to the scope of the present disclosure, with functional equivalents of the claims to be included therein.

### Description of Some of the Reference Characters

1: electronic device; 10: display area;
20: dummy area; 30: pad area;
100: substrate; 110: filling layer;
110a, 110b, 110c: first filling layer, second filling layer, third filling layer;
111: plurality of first openings; 112: plurality of second openings;
111a, 111b: first openings; 112a, 112b, 112c: second openings;
120: reflective barrier;
120a, 120b, 120c: first reflective barrier, second reflective barrier, third reflective barrier;
121: reflective layer; 130: lower electrode;
130a, 130b, 130c: first lower electrode, second lower electrode, third lower electrode;
131a, 131b, 131c: first wiring layer, second wiring layer, third wiring layer;
140: common electrode;
140a, 140b, 140c: first common electrode, second common electrode, third common electrode;
150: planarization layer; 200: light-emitting element;
200a, 200b, 200c: first light-emitting element, second light-emitting element, third light-emitting element;
300: optical element;
300a, 300b, 300c: first optical element, second optical element, third optical element;
400: conductive layer; 500: pad portion

What is claimed is:

1. A display device comprising:
a substrate;
a first common electrode above the substrate;
a second common electrode above the first common electrode and defining first openings;
first light-emitting elements respectively overlapping the first openings in plan view, connected to the first common electrode, below the first common electrode, and arranged in a first direction parallel to a top surface of the substrate; and
second light-emitting elements connected to the second common electrode, below the second common electrode, and arranged in a second direction parallel to the top surface of the substrate.

2. The display device of claim 1, further comprising:
a third common electrode above the second common electrode, and defining second openings overlapping one of the first light-emitting elements or the second light-emitting elements in plan view; and
third light-emitting elements connected to the third common electrode, below the third common electrode, and arranged in a third direction parallel to the top surface of the substrate.

3. The display device of claim 2, further comprising reflective barriers extending in a fourth direction perpendicular to the top surface of the substrate and comprising:
a first reflective barrier spaced apart from at least one of the first light-emitting elements, the second light-emitting elements, or the third light-emitting elements in plan view in a direction parallel to the top surface of the substrate; and
a second reflective barrier overlapping at least one of the first light-emitting elements, the second light-emitting elements, or the third light-emitting elements in the fourth direction.

4. The display device of claim 3, further comprising a reflective layer between the substrate and the first common electrode, and connected to the first reflective barrier.

5. The display device of claim 4, further comprising:
a first filling layer between the substrate and the first common electrode;
a second filling layer between the first common electrode and the second common electrode; and
a third filling layer between the second common electrode and the third common electrode.

6. The display device of claim 5, further comprising a planarization layer above the third common electrode.

7. The display device of claim 6, wherein the first openings are filled with the third filling layer, and
wherein the second openings are filled with the planarization layer.

8. The display device of claim 6, further comprising optical elements above the planarization layer and respectively overlapping the first light-emitting elements, the second light-emitting elements, and the third light-emitting elements.

9. The display device of claim 4, further comprising:
a first lower electrode below, and connected to, one of the first light-emitting elements;
a second lower electrode below, and connected to, one of the second light-emitting elements; and
a third lower electrode below, and connected to, one of the third light-emitting elements.

10. The display device of claim 9, further comprising pixel-driving circuits above the substrate, at least one of the pixel-driving circuits being electrically connected to the first lower electrode through a first wiring layer.

11. The display device of claim 10, wherein the second lower electrode is electrically connected to at least one of the pixel-driving circuits through a second wiring layer and the second reflective barrier.

12. The display device of claim 4, wherein the reflective barriers comprises a conductive material.

13. The display device of claim 4, wherein the first light-emitting elements, the second light-emitting elements, and the third light-emitting elements comprise a first semiconductor layer, an active layer above the first semiconductor layer, and a second semiconductor layer above the active layer.

14. The display device of claim 13, wherein the first semiconductor layer and the second semiconductor layer comprise at least one of II-VI Group nitrides, II-VI Group phosphides, III-V Group nitrides, or III-V Group phosphides.

15. The display device of claim 13, further comprising a current-spreading layer above the second semiconductor layer.

16. A display device comprising:
a substrate,
a first common electrode above the substrate,
a second common electrode above the substrate, at a different layer from the first common electrode, and defining first openings;
first light-emitting elements overlapping the first openings, electrically connected to the first common electrode, and configured to emit first color light; and
second light-emitting elements electrically connected to the second common electrode and configured to emit second color light different from the first color light.

17. The display device of claim 16, further comprising:
a third common electrode above the substrate, at a different layer from the first common electrode and the second common electrode, and defining second openings overlapping the first light-emitting elements or the second light-emitting elements; and
third light-emitting elements electrically connected to the third common electrode and configured to emit third color light different from the first color light and the second color light.

18. The display device of claim 17, further comprising reflective barriers extending in a direction perpendicular to a top surface of the substrate, and comprising:
a first reflective barrier spaced apart from at least one of the first light-emitting elements, the second light-emitting elements, or the third light-emitting elements in plan view in a direction parallel to the top surface of the substrate; and
a second reflective barrier overlapping at least one of the first light-emitting elements, the second light-emitting elements, or the third light-emitting elements in plan view.

19. The display device of claim 18, further comprising a reflective layer between the substrate and the first common electrode and connected to the first reflective barrier.

20. An electronic device comprising:
a processor; and
a display module connected to the processor, and comprising:
a substrate,
a first common electrode above the substrate,
a second common electrode above the first common electrode and defining first openings,
first light-emitting elements respectively overlapping the first openings in plan view, below the first common electrode, and connected to the first common electrode, and
second light-emitting elements below the second common electrode and connected to the second common electrode.
